(19) United States
(12) Patent Application Publication
(10) Pub. No.: US 2017/0304940 A1
(43) Pub. Date: Oct. 26, 2017

(54) DIRECT DIODE LASER OSCILLATOR, DIRECT DIODE LASER PROCESSING APPARATUS, AND REFLECTED LIGHT DETECTING METHOD

(71) Applicant: AMADA HOLDINGS CO., LTD., Kanagawa (JP)

(72) Inventor: Minoru OGATA, Kanagawa (JP)

(73) Assignee: AMADA HOLDINGS CO., LTD., Kanagawa (JP)

(21) Appl. No.: 15/517,746

(22) PCT Filed: Oct. 5, 2015
(86) PCT No.: PCT/JP2015/078177

§ 371 Date: Apr. 7, 2017

(30) Foreign Application Priority Data
Oct. 14, 2014 (JP) 2014-209924

(51) Int. Cl. B23K 26/064; H01S 5/024; H01S 5/00; B23K 26/06; B23K 26/38; B23K 26/08; H01S 5/40; H01S 5/022

(52) U.S. Cl. CPC B23K 26/064; H01S 5/4012; H01S 5/024; H01S 5/02284; B23K 26/06; B23K 26/38; B23K 26/08; H01S 5/005

(57) ABSTRACT

A direct diode laser oscillator includes plurality of LDs that emit laser beams of multiple wavelengths, respectively, a fiber array formed by binding emitting ends of a plurality of feeding fibers that respectively transmit the laser beams of multiple wavelengths emitted from the plurality of LDs, a spectral beam combining unit that spectral-beam-combines the laser beams of multiple wavelengths emitted from the fiber array, a reflected light detecting fiber that is arranged adjacent to the fiber array and receives, through the spectral beam combining unit, reflected light of the laser beams of multiple wavelengths reflected by a work material, and a photodetector that detects the reflected light emanating from the reflected light detecting fiber.

### TECHNICAL FIELD

The present invention relates to a direct diode laser oscillator, a direct diode laser processing apparatus, and a reflected light detecting method.

### BACKGROUND ART

Known laser processing apparatuses for processing sheet metal employ, as a laser beam source, a carbon dioxide (CO₂) gas laser oscillator, a YAG laser oscillator, or a fiber laser oscillator. The fiber laser oscillator is superior in beam quality to the YAG laser oscillator and has advantages of providing a very high oscillation efficiency and the like. Due to this, the fiber laser processing apparatus using the fiber laser oscillator is used in industrial fields, in particular, in sheet metal processing (cutting, welding, and the like).

Developed in recent years is a direct diode laser (DDL) processing apparatus that uses, as a laser beam source, a direct diode laser oscillator. The DDL processing apparatus employs a plurality of laser diodes (LDs), superimposes user beams into a multiple-wavelength laser beam, and transmits the laser beam through a transmission fiber to a processing head. The laser beam emitted from an end face of the transmission fiber is concentrated through and irradiated from collimating and condensing lenses onto a work material.

In sheet metal processing (in particular, cutting) with a laser beam, part of the laser beam irradiating a work material is not absorbed and is reflected so that the reflected light overheats parts of the laser processing apparatus and badly affects the processing. To cope with this problem, a method of detecting reflected light from a work material has been proposed for the laser processing apparatus that employs, as a laser light source, the YAG laser oscillator, CO2 laser oscillator, or fiber laser oscillator. Related arts are, for example, Japanese Unexamined Patent Application Publications No. H11-211556 (Patent Literature 1), No. 2012-179627 (Patent Literature 2), and No. 2013-55084 (Patent Literature 3).

### SUMMARY OF INVENTION

### Problems to be Solved by Invention

Concerning the DDL processing apparatus, reflected light from a work material has a possibility of badly affecting parts of the DDL processing apparatus. However, no thorough examinations have been made on a reflected light detecting method appropriate for the DDL processing apparatus.

In consideration of the above-mentioned problem, the present invention provides a direct diode laser oscillator, a direct diode laser processing apparatus, and a reflected light detecting method, capable of easily detecting, when processing a work material with the direct diode laser processing apparatus, reflected. light of a laser beam emanated to the work material.

### Means to Solve Problems

According to an aspect, of the present invention, the direct diode laser oscillator, direct diode laser processing apparatus, and reflected light detecting method include a plurality of laser diodes that emit laser beams of multiple wavelengths, respectively, a fiber array formed by binding emitting ends of a plurality of feeding fibers that respectively transmit the laser beams of multiple wavelengths emitted from the plurality of laser diodes, a spectral beam combining unit that spectral-beam-combines the laser beams of multiple wavelengths emitted from the fiber array, a reflected light detecting fiber that is arranged adjacent to the fiber array and receives, through the spectral beam combining unit, reflected light of the laser beams of multiple wavelengths reflected by a work material, and a photodetector that detects the reflected light emanating from the reflected light detecting fiber.

### BRIEF DESCRIPTION OF DRAWINGS

FIG. 1 is a perspective view illustrating an example of a DDL processing apparatus according to an embodiment of the present invention.

FIG. 2(a) is a front view illustrating an example of a user oscillator according to the embodiment of the present invention and FIG. 2(b) is a side view illustrating the example of the laser oscillator according to the embodiment of the present invention.

FIG. 3 is a schematic view illustrating the example of the laser oscillator according to the embodiment of the present invention.

FIG. 4 is a schematic view illustrating a laser beam oscillating state of the laser oscillator according to the embodiment of the present invention.

FIG. 5 is a schematic view illustrating a reflected light detecting state of the laser oscillator according to the embodiment of the present invention.

### MODE OF IMPLEMENTING INVENTION

With reference to the drawings, an embodiment of the present invention will be explained. In the following description of the drawings, the same or like parts are represented with the same or like reference marks.

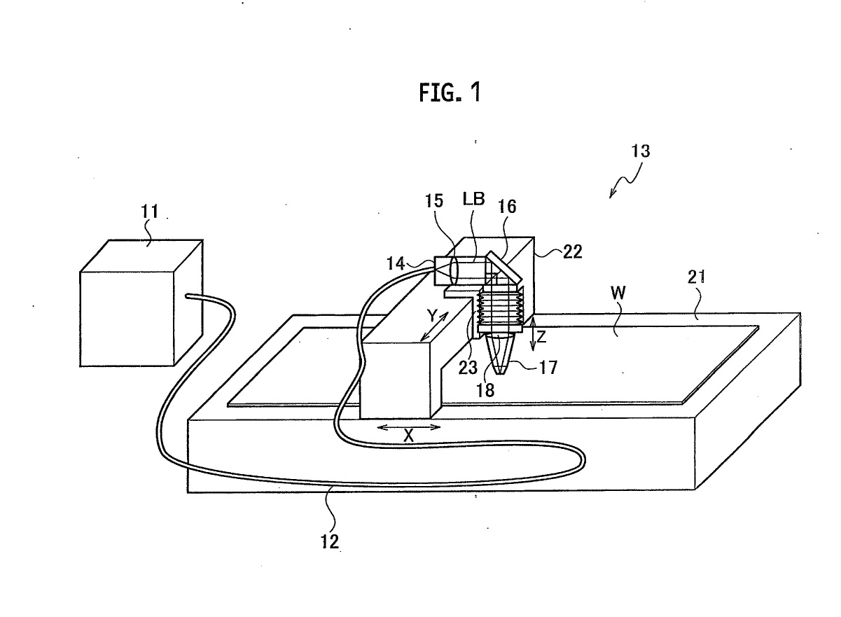

With reference to FIG. 1, a general configuration of a direct diode laser (hereinafter referred to as “DDL”) processing apparatus according to the embodiment of the present invention will be explained. The DDL processing apparatus according to the embodiment of the present invention includes, as illustrated in FIG. 1, a laser oscillator 11 that emits a multiple-wavelength laser beam LB, a transmission fiber (process fiber) 12 that transmits the laser beam LB emitted from the laser oscillator 11, and a laser processing machine 13 that condenses the laser beam LB transmitted through the transmission fiber 12 into one having a high-energy concentration and emits the same toward a work material (work) W.

The laser processing machine 13 includes collimator unit 14 that converts, through a collimator lens 15, the laser beam LB emitted from the transmission fiber 12 into a substantial parallel beam, a diffraction grating as a dispersing element 16 that diffracts the laser beam LB converted into the substantial parallel beam in a downward Z-axis direction orthogonal to X- and Y-axis directions, and a processing head 17 that condenses, through a condensing lens 18, the laser beam LB diffracted by the dispersing element 16. Although not illustrated in FIG. 1, the collimator unit 14 incorporates a lens driving unit that drives the collimator lens 15 in a direction, e.g. X-axis direction, parallel to an optical axis. To control the lens driving unit, the DDL processing apparatus further includes a controller.

The laser processing machine 13 also includes a processing table 21 on which the work material W is placed, a portal X-axis carriage 22 that moves in the X-axis direction on the processing table 21, and a Y-axis carriage 23 that moves on the X-axis carriage 22 in the Y-axis direction orthogonal to the X-axis direction. The collimator lens 15 in the collimator unit 14, the dispersing element 16, and the condensing lens 18 in the processing head 17 are preliminarily adjusted to the optical axis, are fixed to the Y-axis carriage 23, and are moved together with the Y-axis carriage 23 in the Y-axis direction. It is possible to arrange a Z-axis carriage movable in an up-down direction with respect to the Y-axis carriage 23 and set the condensing lens 18 on the Z-axis carriage.

The DDL processing apparatus according to the embodiment of the present invention irradiates the work material W with the laser beam LB that has been condensed through the condensing lens 18 to have a smallest condensed diameter, i.e. minimum condensed diameter. While coaxially jetting an assist gas to remove meltage, the DDL processing apparatus moves the X-axis carriage 22 and Y-axis carriage 23. With this, the DDL processing apparatus cuts and processes the work material W. The work material W may be made from various materials such as stainless steel, mild steel, and aluminum. The thickness of the work material W may be, for example, about 0.1 mm to 50 mm.

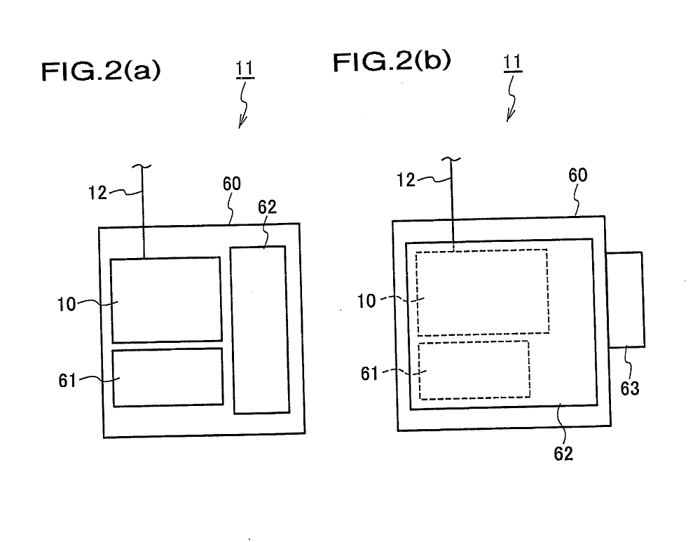

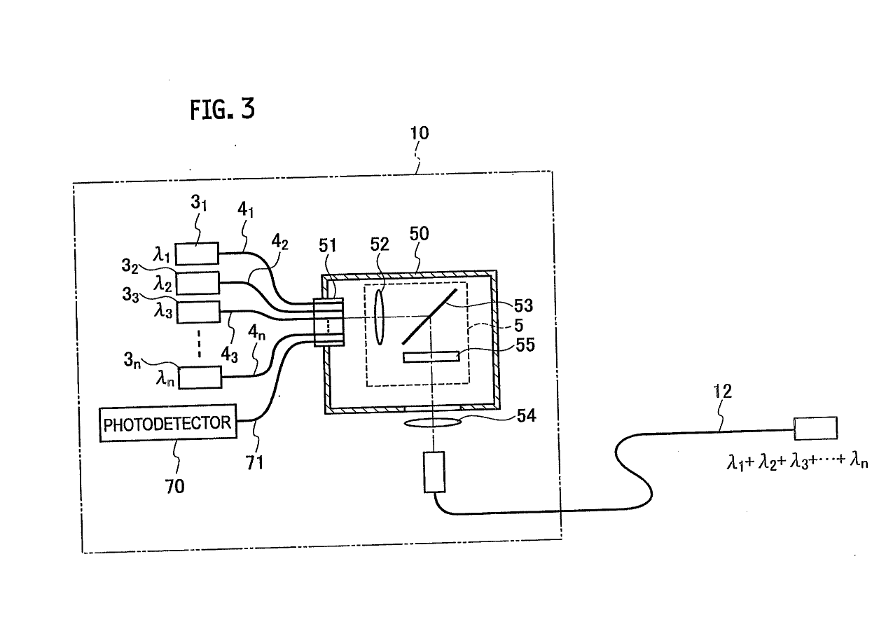

With reference to FIGS. 2 and 3, the laser oscillator 11 will be explained. The laser oscillator 11 includes, as illustrated FIGS. 2(a) and 2(b), a casing 60, a DDL module 10 accommodated in the casing 60 and connected to the transmission fiber 12, a power source unit 61 accommodated in the casing 60 and supplying power to the DDE module 10, a control module 62 accommodated in the casing 60 and controlling outputs of the DDL module 10 and others, and the like. Arranged outside the casing 60 is an air conditioning device 63 to adjust the temperature and humidity of the inside of the casing 60.

The DDL module 10, as illustrated in FIG. 3, superimposes and outputs a multiple-wavelength laser beam having multiple wavelengths λ1 (lambda 1), λ2, λ3, . . . , λn (hereinafter referred to as “{λi}”). The DDL module 10 includes a plurality of laser diodes (hereinafter referred to as “LDs”) 3₁, 3₂, 3₃, . . . , 3n (n being an integer equal to or greater than 4), an optical box 50 connected through feeding fibers 4₁, 4₂, 4₃, . . . , 4n to the LDs 3₁, 3₂, 3₃, . . . , 3n, and a condensing lens 54 that condenses a laser beam from the optical box 50 and makes the same incident to the transmission fiber 12.

Adoptable as the plurality of LDs 3_{1,} 3₂, 3₃, . . . , 3n (hereinafter referred to as the plurality of LDs 3) are various kinds of semiconductor lasers. Combinations of kind and number for the plurality of LDs 3 are not particularly limited and are properly selected according to a sheet metal processing purpose. The wavelengths λ1, λ2, λ3, . . . , λn of the LDs 3 are selectable from the ranges of, for example, smaller than 1000 nm, 800 nm to 990 nm, and 910 nm to 950 nm.

The laser beams of multiple wavelengths {λi} are managed and controlled block by block based on, for example, wavelength bands. Outputs of the laser beams are variably and individually adjusted depending on the wavelength bands thereof. Outputs of all wavelength bands are adjustable in such a way as to maintain a constant absorptance.

A cutting process is achieved by simultaneously driving the plurality of LDs 3 and by jetting a proper assist gas such as an oxygen or nitrogen gas to the vicinities of focusing positions. With this, the laser beams with different wavelengths from the LDs 3 cooperate with one another and with the assist gas such as an oxygen gas to melt the work material at high speed. Meltage is blown by the assist gas and the work material is speedily cut.

The optical box 50 includes a fixing unit 51 that binds and fixes emitting ends of the feeding fibers 4₁, 4₂, 4₃, . . . , 4n to form a fiber array 4 and a spectral beam combining unit 5 that conducts spectral beam combining on the laser beams of multiple wavelengths {λi}.

The spectral beam combining unit 5 includes a collimator lens 52 that makes the laser beams from the feeding fibers 4₁, 4₂, 4₃, . . . , 4n parallel to one another, a diffraction grating 53 that diffracts the laser beams of multiple wavelengths {λi} to make optical axes thereof coincide with one another, and a partial reflection coupler 55 that constitutes a resonator together with a reflection face arranged at rear ends of the plurality of LDs 3. Although the partial reflection coupler 55 in FIG. 3 is arranged after the diffraction grating 53 as an example, the arranging position of the partial reflection coupler 55 is not limited to this case.

According to the embodiment illustrated in FIG. 3, a first end of a reflected light detecting fiber 71 is arranged adjacent to the fiber array 4 consisting of the emitting ends of the feeding fibers 4₁, 4₂, 4₃, . . . , 4n. More precisely, the first end of the reflected light detecting fiber 71 faces, with its incident end (a right-side end in FIG. 3), the collimator lens 52, is in parallel with the emitting ends of the feeding fibers 4₁, 4₂, 4₃, . . . , 4n and is bound and fixed, like the feeding fibers 4₁, 4₂, 4₃, . . . , 4n with the fixing unit 51. The material and shape of the reflected light detecting fiber 71 may be similar to those of the feeding fibers 4₁, 4₂, 4₃, . . . , 4n.

Instead of using the fixing unit 51 to fix the feeding fibers 4₁, 4₂, 4₃, . . . , 4n and reflected light detecting fiber 71, the feeding fibers 4₁, 4₂, 4₃, . . . , 4n and reflected detecting fiber 71 may be bonded together.

Like the emitting ends of the feeding fibers 4₁, 4₂, 4₃, . . . , 4n the first end of the reflected light detecting fiber 71 is arranged to face the spectral beam combining unit 5 and serves as an incident end of reflected light. A second end of the reflected light detecting fiber 71 is connected to a photodetector 70. The photodetector 70 is connected to the controller 62 illustrated in FIG. 2(a).

An example of the reflected light detecting method used when the DDL processing apparatus according to the embodiment of the present invention carries out sheet metal processing will be explained.

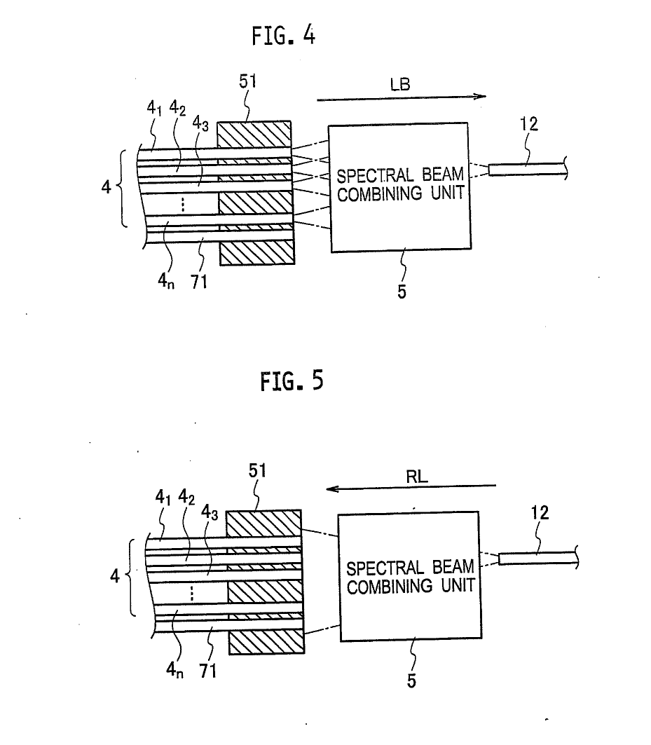

The LDs 3₁, 3₂, 3₃, . . . , 3n illustrated in FIG. 2 emit laser beams with multiple wavelengths, the laser beams being transmitted through the feeding fibers 4₁, 4₂, 4₃, . . . , 4n. AS illustrated in FIG. 4, the user beams with multiple wavelengths transmitted through the feeding fibers 4₁, 4₂, 4₃, . . . , 4n are made incident to the spectral beam combining unit 5. The spectral beam combining unit 5 spectral-beam-combines the laser beams into a multiple-wavelength laser beam (output) LB, which is transmitted through the transmission fiber 12. In FIGS. 4 and 5, the condensing lens 54 that is present between the spectral beam combining unit 5 and the transmission fiber 12 is omitted. The collimator lens 15, condensing lens 18, and the like illustrated in FIG. 1 concentrate the multiple-wavelength laser beam to the work material W, thereby processing the work material W.

At this time, part of the laser beam (output) LB irradiating the work material W is not absorbed and is reflected. The reflected light RL may return through the transmission fiber 12 to the laser oscillator 11. As illustrated in FIG. 5, the reflected light RL made incident to the spectral beam combining unit 5 from the transmission fiber 12 propagates or scatters in the spectral beam combining unit 5, emanates toward the fiber array 4, and enters into the feeding fibers 4₁, 4₂, 4₃, . . . , 4n and reflected light detecting fiber 71.

At this time, the reflected light RL entering the feeding fibers 4₁, 4₂, 4₃, . . . , 4n and reflected light detecting fiber 71 has, due to propagation within the transmission fiber 12 or dispersion by the optical parts, a sufficiently averaged intensity distribution in an area over the end faces of the adjacent feeding fibers 4₁, 4₂, 4₃, . . . , 4n and reflected light detecting fiber 71. Accordingly, it is assumed that the reflected light enters at a similar ratio into the respective feeding fibers 4₁, 4₂, 4₃, . . . , 4n and reflected light detecting fiber 71.

The photodetector 70 illustrated in FIG. 3 detects a light intensity of the reflected light transmitted through the reflected light detecting fiber 71. Data on the detected light intensity of the reflected light is usable for monitoring a process. In the case of, for example, a cutting process of the work material W, the controller 62 refers to the data on the light intensity of the reflected light detected by the photodetector 70 and determines whether or not the work material W has been cut through.

The controller 62 may provide an NC apparatus with an alert if the light intensity of the reflected light detected by the photodetector 70 is equal to or greater than a predetermined threshold, i.e., an intensity to possibly break the LDs 3₁, 3₂, 3₃, . . . , 3n. The predetermined threshold may be stored in a memory or the like of the controller 62.

As explained above, the present invention arranges the reflected light detecting fiber 71 adjacent to the fiber array 4 of the plurality of DLs LD3 serving as light sources of the DDL processing apparatus and detects reflected light transmitted through the reflected light detecting fiber 71 with the photodetector 70, thereby realizing a safe and inexpensive configuration to observe the reflected light.

Since the reflected light detecting fiber 71 is arranged adjacent to the fiber array 4, it is possible to observe reflected light equivalent to one returning to the LDs 3₁, 3₂, 3₃, . . . , 3n that tend to suffer the influence of the reflected light. It is possible, therefore, to obtain reliable data on an intensity of the reflected light.

The DDE resonator 11 spectral-beam-combines laser beams having multiple wavelengths, and therefore, is resistant to reflected light compared to a fiber laser processing apparatus and is not required, unlike the fiber laser processing apparatus, to suppress reflected light to be made incident to an amplification part. Since the laser beams with multiple wavelengths are combined in space, the reflected light is easy to detect.

### Other Embodiments

Although the present invention has been explained on the basis of embodiment, it should not be understood that the explanation and drawings that form part of the disclosure limit the present invention. The disclosure may clarify, for persons skilled in the art, various substitutes, alternatives, and applications for the present invention.

For example, FIG. 2 illustrates the reflected light detecting fiber 7 adjacent to one of juxtaposed ends of the fiber array 4, i.e., the feeding fiber 4n. Instead, the reflected light detecting fiber 7 may be arranged between adjacent ones of the feeding fibers 4₁, 4₂, 4₃, . . . , 4n of the fiber array 4. It is also possible to arrange two or more reflected light detecting fibers 7. For example, two reflected light detecting fibers may be arranged on each side of the juxtaposed ends of the fiber array 4.

The kind of sheet metal processing to which the DDL processing apparatus and reflected light detecting method for the apparatus according to the embodiment of the present invention are applied is not particularly limited. They are applicable not only to cutting but also to laser forming, annealing, abrading, and other kinds of sheet metal processing.

In this way, the present invention naturally covers various embodiments and the like that are not explained herein. Accordingly, technical scopes of the present invention are determined only by invention specific matters that are pertinent to the above-mentioned explanation and the claims.

According to the present invention, there are provided a direct diode laser oscillator, a direct diode laser processing apparatus, and a reflected light detecting method, capable of easily detecting reflected light of a laser beam emitted to a work material when the work material is processed with the direct diode laser processing apparatus.

### UNITED STATES DESIGNATION

In connection with United States designation, this international patent application claims the benefit of priority under 35 U.S.C. 119(a) to Japanese Patent Application No. 2014-209924 filed on Oct. 14, 2014 whose disclosed contents are incorporated herein by reference.

1. A direct diode laser oscillator comprising:
a plurality of laser diodes emitting laser beams of multiple wavelengths, respectively;
a fiber array formed by binding emitting ends of a plurality of feeding fibers that respectively transmit the laser beams of multiple wavelengths emitted from the plurality of laser diodes;
a spectral beam combining unit that spectral-beam-combines the laser beams of multiple wavelengths emitted from the fiber array;
a reflected light detecting fiber arranged adjacent to the fiber array and receiving through the spectral beam combining unit reflected light of the laser beams of multiple wavelengths reflected by a work material; and
a photodetector detecting the reflected light emanating from the reflected light detecting fiber.

2. The direct diode laser oscillator according to claim 1, further comprising
a controller controlling outputs of the plurality of laser diodes according to an intensity of the reflected light detected by the photodetector.

3. A direct diode laser processing apparatus comprising:
the direct diode laser oscillator according to claim 1;
a transmission fiber transmitting the laser beams of multiple wavelengths spectral-beam-combined by the spectral beam combining unit; and
a laser processing machine processing the work material with the laser beams of multiple wavelengths transmitted through the transmission fiber.

4. A reflected light detecting method for the direct diode laser oscillator according to claim 1, comprising:
making reflected light of the laser beams of multiple wavelengths reflected by the work material incident, through the spectral beam combining unit, into a reflected light detecting fiber; and
controlling outputs of the plurality of laser diodes according to the reflected light emitted from the reflected light detecting fiber.
